(19) United States
(12) Patent Application Publication
(10) Pub. No.: US 2025/0329392 A1
(43) Pub. Date: Oct. 23, 2025

(54) CONTROL DEVICE, CONTROL METHOD AND MEMORY SYSTEM

(71) Applicant: Winbond Electronics Corp., Taichung City (TW)

(72) Inventor: Liang-Hsiang Chiu, Hsinchu County (TW)

(73) Assignee: Winbond Electronics Corp., Taichung City (TW)

(21) Appl. No.: 19/034,532

(22) Filed: Jan. 22, 2025

(30) Foreign Application Priority Data
Apr. 18, 2024 (TW) 113114564

(51) Int. Cl. G11C 16/20; G11C 16/30

(52) U.S. Cl. CPC G11C 16/20; G11C 16/30

(57) ABSTRACT

A control device, a control method, and a memory system are disclosed. The control device controls the memory system, and includes a first peripheral circuit group, driven by a first voltage in a stand-by mode; a second peripheral circuit group, coupled to the first peripheral circuit group and driven by a second voltage in the stand-by mode; and a third peripheral circuit group, coupled between the first and second peripheral circuit groups. A structure of the third peripheral circuit group is a fuse memory circuit, and when the memory system enters a deep power down mode, the fuse memory circuit operates an operating voltage between an upper limit value and a lower limit value. The upper limit value is lower than the second voltage.

### CROSS-REFERENCE TO RELATED APPLICATION

This application claims the priority benefit of Taiwan application serial no. 113114564, filed on Apr. 18, 2024. The entirety of the above-mentioned patent application is hereby incorporated by reference herein and made a part of this specification.

### BACKGROUND

### Technical Field

This disclosure relates to a control device, a control method, and a memory system.

### Description of Related Art

The current power management mode of the memory can support Deep Power Down (DPD) mode. When the memory is not needed temporarily, it can be put to sleep without updating the memory, which reduces the power consumption during standby. However, the DPD current ICC2 in DPD mode is more stringent (less than 1 μA). When the process is minimized, the shutdown leakage current Ioff of the element tends to increase, especially at high temperatures. Current products turn off the internal power supply int_VDD in DPD mode to reduce the shutdown leakage current Ioff of the element to meet the design specification of ICC2.

The voltage settings required for reading, programming, and erasing are normally stored in NAND memory using a fuse memory cell. The current practice is to turn off the internal power int_VDD when in DPD mode. However, when leaving DPD mode, the information in the fuse memory cell needs to be re-stored in the fuse register when the internal power supply int_VDD is turned on. As a result, the fuse needs to be re-stored, and the recovery time tRES may increase to more than 3 ms. Thus, how to shorten the recovery time tRES may be an urgent problem to be solved.

### SUMMARY

The disclosure provides a control device configured to control a memory system. The control device includes: a first peripheral circuit group, driven by a first voltage when the memory system is in a stand-by mode; a second peripheral circuit group, coupled to the first peripheral circuit group, driven by a second voltage when the memory system is in the stand-by mode; a third peripheral circuit group, coupled between the first peripheral circuit group and the second peripheral circuit group. A structure of the third peripheral circuit group is a fuse memory circuit. When the memory system enters a deep power down mode based on a deep power down mode signal being a first logical value, the fuse memory circuit operates an operating voltage between an upper limit value and a lower limit value, and the upper limit value is lower than the second voltage.

The disclosure provides a memory system including a memory array and a control device for controlling the memory array. The control device includes: a first peripheral circuit group, coupled to the memory array, driven together with the memory array by a first voltage when the memory array is in a stand-by mode; a second peripheral circuit group, coupled to the memory array and the first peripheral circuit group, driven by a second voltage when the memory array is in the stand-by mode; a third peripheral circuit group, coupled between the first peripheral circuit group and the second peripheral circuit group. A structure of the third peripheral circuit group is a fuse memory circuit. When the memory system enters a deep power down mode based on a deep power down mode signal being a first logical value, the fuse memory circuit operates an operating voltage between an upper limit value and a lower limit value, and the upper limit value is lower than the second voltage.

The disclosure provides a control method for controlling a memory system. The memory system has a control device, the control device includes a first peripheral circuit group operating at a first voltage, a second peripheral circuit group operating at a second voltage, and a third peripheral circuit group disposed independently from the first peripheral circuit group and the second circuit group. The control method includes the following. Whether the memory system is going to enter a deep power down mode is determined. When determining that the memory system enters the deep power down mode, an operating voltage of a fuse register in the third peripheral circuit group is detected, in which the fuse register is configured to store operation information for an operation of the memory system. Until existing the deep power down mode, based on the detected operating voltage, the operating voltage of the fuse register is enabled to be between an upper limit value and a lower limit value. The upper limit value is lower than the second voltage.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a circuit block diagram of a memory system according to an embodiment of the disclosure.

FIG. 2 is a block diagram of a fuse memory circuit shown in FIG. 1.

FIG. 3 is an operation timing diagram of a fuse memory circuit according to an embodiment of the disclosure.

FIG. 4 is a schematic diagram of a low voltage detection circuit in a fuse memory circuit according to an embodiment of the disclosure.

FIG. 5 is a schematic flow chart of a control method according to an embodiment of the disclosure.

### DESCRIPTION OF THE EMBODIMENTS

A fuse register in a memory system stores some voltage information required for programming, erasing, and reading operations of the memory, such as voltage values of various operations. When performing a specific operation, the memory reads corresponding information from the fuse register to perform the specific operation.

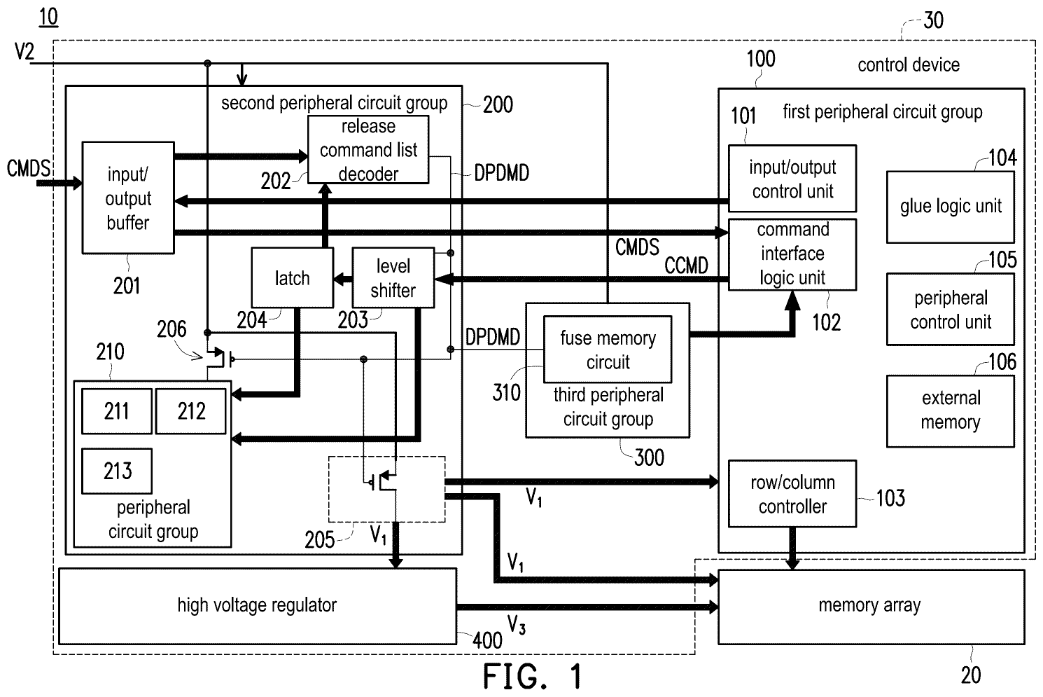

FIG. 1 is a schematic configuration diagram of a memory system according to an embodiment of the disclosure. In this embodiment, a memory system 10 includes a memory array 20 and a control device 30 controlling the memory array 20. In a stand-by mode, the memory array 20 is driven by a first voltage V1. The control device 30 includes a peripheral circuit group 100 and a peripheral circuit group 200. The peripheral circuit group 100 is coupled to the memory array 20. In the stand-by mode, the peripheral circuit group 100 is driven by the first voltage V1. That is, in the stand-by mode, the peripheral circuit group 100 and the memory array 20 are driven together by the first voltage V1. In addition, the peripheral circuit group 200 is coupled to the memory array 20 and the peripheral circuit group 100. The peripheral circuit group 200 is driven by a second voltage V2. In this architecture, the peripheral circuit group 100 may be regarded as a VDD power domain block. The peripheral circuit group 200 may be regarded as a VCC power domain block.

In this embodiment, the peripheral circuit group 100 may include an input/output control unit 101 and a command interface logic unit 102. The command interface logic unit 102 may be connected to a peripheral circuit group 300. In addition, the peripheral circuit group 100 may at least include a row/column controller 103, a glue logic unit 104, a peripheral control unit 105, and an external memory 106 such as SRAM or ROM.

The command interface logic unit 102 is coupled to an input/output buffer 201 of the peripheral circuit group 200. The command interface logic unit 102 receives a command list CMDS through the input/output buffer 201. In the stand-by mode, the command interface logic unit 102 recognizes the command list CMDS. When recognizing that the command list CMDS is a deep power down execution command list, the command interface logic unit 102 decodes the deep power down execution command list to generate a control command CCMD, and provides the control command CCMD to the peripheral circuit group 200.

The peripheral circuit group 200 also includes a level shifter 203, a latch 204, a voltage

regulation circuit 205, a power switch 206, and a peripheral circuit group 210. The level shifter 203 is coupled to the peripheral circuit group 100. The level shifter 203 shifts a voltage level of the control command CCMD. The latch 204 is coupled to the level shifter 203 and a release command list decoder 202. The latch 204 latches the control command CCMD and provides the control command CCMD to the release command list decoder 202. The release command list decoder 202 provides a DPD mode signal DPDMD having a first logic value (e.g., a high level H) according to the latched control command CCMD.

In this embodiment, the voltage regulation circuit 205 is coupled to the memory array 20, the peripheral circuit group 100, and the release command list decoder 202. The voltage regulation circuit 205 adjusts the second voltage V2 (VCC) to the first voltage V1 (VDD) according to a deep power down signal DPDMD having a second logic value, and provides the first voltage V1 (VDD) to the memory array 20 and the peripheral circuit group 100. The voltage regulation circuit 205 stops providing the first voltage V1 (VDD) to the memory array 20 and the peripheral circuit group 100 according to the deep power down signal DPDMD having the first logic value.

The power switch 206 is coupled to the peripheral circuit group 210 and the release command list decoder 202. The power switch 206 provides the second voltage V2 to the peripheral circuit group 210 according to the DPD mode signal DPDMD having the first logic value, and stops providing the second voltage V2 to the peripheral circuit group 210 according to the DPD mode signal DPDMD having the first logic value. Thus, the peripheral circuit group 210 is driven by the second voltage V2 in the stand-by mode, and stops being driven in the DPD mode. That is, in the DPD mode, only the input and output buffer 201, the release command list decoder 202, the level shifter 203, and the latch 204 maintain operation.

In addition, the peripheral circuit group 210 includes, for example, a power-on circuit 211, a bandgap circuit 212, an analog circuit 213, and other circuits suitable for entering the stand-by mode.

The control device 30 further includes a high voltage regulator 400. The high voltage regulator 400 is coupled to the voltage regulation circuit 205 of the peripheral circuit group 200. The high voltage regulator 400 regulates the first voltage V1 provided by the voltage regulation circuit 205 to a third voltage V3 in the stand-by mode, and provides the third voltage V3 to the memory array 20. A voltage value of the third voltage V3 is higher than a voltage value of the second voltage V2. In the DPD mode, the high voltage regulator 400 cannot receive the first voltage V1 provided by the voltage regulation circuit 205. Thus, the high voltage regulator 400 is disabled in the DPD mode and does not provide the third voltage V3.

According to the embodiment of the disclosure, the memory system 10 also includes the peripheral circuit group 300, configured to dispose a fuse memory circuit 310. Through the fuse memory circuit 310, when the memory system 10 enters the DPD mode, the fuse memory circuit 310 can still maintain operation, that is, voltage settings required for memory operation are continuously stored. In other words, the embodiment of the disclosure separates an operating voltage (i.e., an internal power) VDDREG of the fuse register, so that the memory system 10 can maintain a voltage at which the fuse register can operate normally when entering the DPD mode. That is, in the DPD mode, the fuse memory circuit 310 is not disabled and continues to operate.

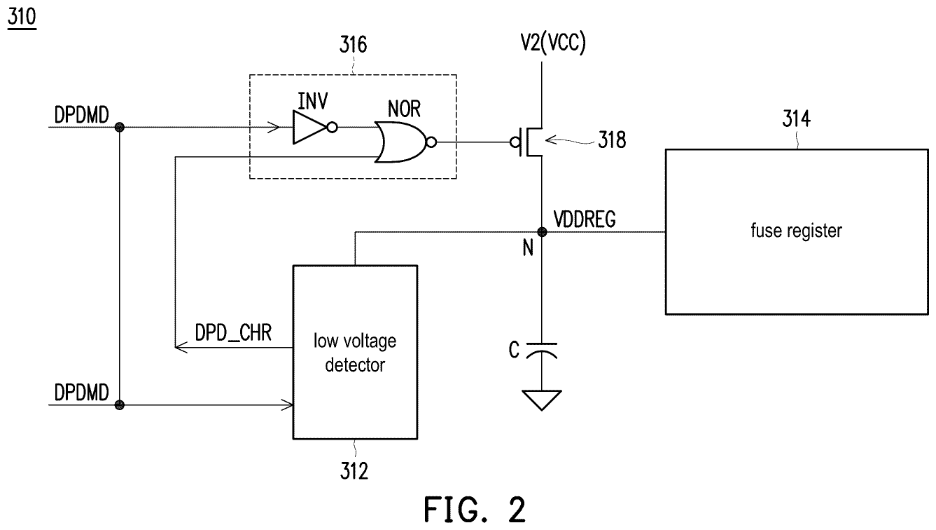

As shown in FIG. 2, according to the implementation of the disclosure, for example, the fuse memory circuit 310 includes a low voltage detector 312, a fuse register 314, a logic circuit 316, a transistor 318, and a capacitor C.

The fuse memory circuit 310 is coupled between the peripheral circuit group 100 and the peripheral circuit group 200 of the control device 30. In addition, the fuse memory circuit 310 receives the DPD mode signal DPDMD from the peripheral circuit group 200. Different from the peripheral circuit group 100 that operates in a first voltage domain and the peripheral circuit group 200 that operates in a second voltage domain, the fuse memory circuit 310 operates in a third voltage domain. The third voltage domain is an operating voltage VDDREG that allows the fuse register 314 in the fuse memory circuit 310 to operate in the DPD mode, which can be slightly smaller than the second voltage V2 (i.e., VCC).

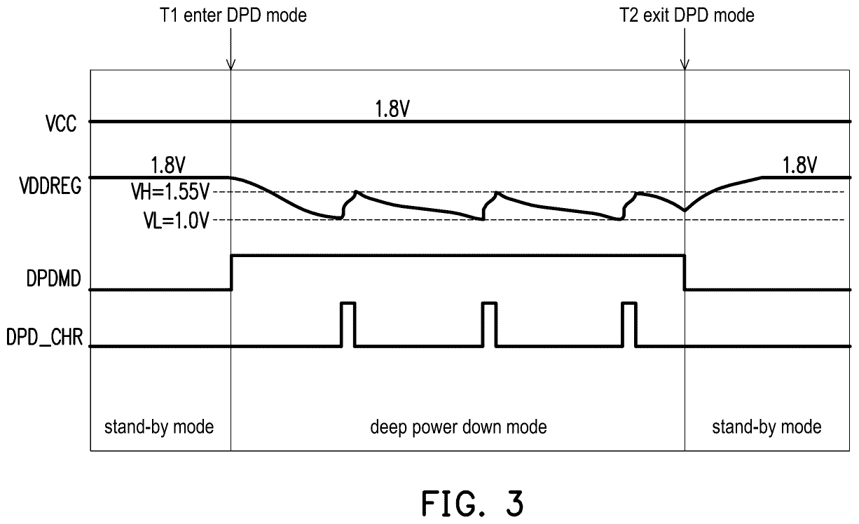

As shown in FIG. 2 and FIG. 3, the fuse register 314 is configured to store voltage information when the memory array 20 performs various operations (after leaving the DPD mode). The low voltage detector 312 is configured to detect the operating voltage VDDREG of the fuse register 314, and outputs a low voltage detection signal DPD_CHR based on the magnitude of the operating voltage VDDREG. As shown in FIG. 3, at time point T1, the memory system 10 enters the DPD mode after the DPD mode signal DPDMD becomes a high level of the first logic value. At this time, the original operating voltage VDDREG of the fuse register 314 is equal to the second voltage VCC. Once entering the DPD mode, the operating voltage VDDREG begins to decrease and is lower than the second voltage VCC.

When the operating voltage VDDREG continues to decrease and reaches a lower limit value VL, the low voltage detection signal DPD_CHR becomes the first logic value (high level), that is, the low voltage detector 312 outputs the low voltage detection signal DPD_CHR with high level. Next, the operating voltage VDDREG starts to rise by charging the capacitor C (described later). When the operating voltage VDDREG reaches an upper limit value VH, the low voltage detector 312 outputs the low voltage detection signal DPD_CHR with the second logic value (low level). In this way, in the DPD mode, the operating voltage VDDREG repeatedly changes between the upper limit value VH and the lower limit value VL, thereby allowing the fuse register 314 to maintain operation in the DPD mode. In this example, the upper limit value VH and the lower limit value VL are the lowest voltage range that can maintain the operation of the fuse register 314 in the DPD mode. In an example, when the second voltage V2 (i.e., VCC) of the peripheral circuit group 200 is 1.8V, the upper limit value VH can be set to 1.55V, and the lower limit value VL can be set to 1.0V.

The logic circuit 316 is coupled to the low voltage detector 312 to receive the deep power down mode signal DPDMD and the low voltage detection signal DPD_CHR, and to perform logical operations on the two. In addition, the transistor 318 has a gate as a control terminal, a first terminal, and a second terminal (source/drain). The control terminal is coupled to the output of the logic circuit 316, and the first terminal of the transistor 318 is coupled to the second voltage V2 (i.e., VCC). The transistor 318 switches based on a result of logic operation of the logic circuit 316. Furthermore, the capacitor C has a first terminal coupled to the second terminal of the transistor 318 and a second terminal coupled to ground. In addition, a coupling node N of the transistor 318 and the capacitor C is further coupled to the fuse register 314 to provide the operating voltage VDDREG.

Additionally, for example, the logic circuit 316 may include an inverter INV and an NOR gate NOR. In this case, the transistor 318 may be a PMOS transistor. An input terminal of the inverter INV receives the DPD mode signal DPDMD. The inverter INV can invert the received DPD mode signal DPDMD. An output terminal of the inverter INV is coupled to an input terminal of the NOR gate NOR. The other input terminal of the NOR gate NOR receives the low voltage detection signal DPD_CHR from the low voltage detector 312. The output of the NOR gate NOR is used as an output terminal of the logic circuit 316 and is coupled to the gate of the transistor 318. Thus, the switching of the transistor 318 can be controlled by the result of logic operation of the logic circuit 316. In addition, the logic circuit 316 and the transistor 318 may also adopt other architectures, as long as the above control method can be achieved, the disclosure is not particularly limited.

Next, the operation of the fuse memory circuit 310 is further described with reference to FIG. 2 and FIG. 3. As shown in FIG. 3, at time T1, that is, in the stand-by mode, the DPD mode signal DPDMD is low level (L state), that is, the memory system 10 does not enter the DPD mode. At this time, the low voltage detection signal DPD_CHR output by the low voltage detector 312 of the fuse memory circuit 310 is low level L. During this period, the operating voltage VDDREG of the fuse register 314 of the fuse memory circuit 310 is substantially equal to the second voltage V2, that is, VCC. During this period, the DPD mode signal DPDMD is low level and the low voltage detection signal DPD_CHR is low level L. The logic circuit 316 outputs a signal of low level L based on the result of logic operation of the two. As a result, the transistor 318 is turned on and provides the operating voltage VDDREG, which is substantially equal to the second voltage V2 (i.e., VCC), to the fuse register 314. At the same time, the capacitor C is also charged.

At time T1, when the memory system 10 enters the DPD mode, the DPD mode signal DPDMD becomes a high level (H state). At this time, after the logic circuit 316 receives the DPD mode signal DPDMD and the low voltage detection signal DPD_CHR, logic operation is performed and a high-level signal is output, and the transistor 318 is turned off. At this time, the capacitor C begins to charge the fuse register 314 to provide the operating voltage VDDREG of the fuse register 314. At the same time, the low voltage detector 312 starts to operate.

When the low voltage detector 312 detects that the operating voltage VDDREG of the fuse register 314 drops to a preset lower limit value VL, the low voltage detector 312 outputs a high-level low-voltage detection signal DPD_CHR. At this time, the operation result of the logic circuit 316 turns on the transistor 318 again to provide the operating voltage to the fuse register 314 and to charge the capacitor C at the same time.

Afterwards, when the operating voltage VDDREG reaches a preset upper limit value VH, the low voltage detector 312 outputs the low voltage detection signal DPD_CHR with low level. At this time, the operation result of the logic circuit 316 turns off the transistor 318 again. At this time, the quiescent current and leakage current required by the fuse register 314 are temporarily provided by the capacitor.

Thus, when the memory system 10 enters the DPD mode, the low voltage detection circuit 312 of the fuse memory circuit 310 continuously detects the operating voltage VDDREG of the fuse register 314, so that the operating voltage VDDREG can be repeatedly maintained at the lower limit value VL and upper limit value VH. That is, the above actions continue to charge and discharge the fuse register 314 and the capacitor C until the DPD mode is exited.

At time point T2, the memory system 10 exits the DPD mode. At this point, the memory system 10 returns to the stand-by mode. At this time, the DPD mode signal DPDMD is low level (L state). The low voltage detection signal DPD_CHR output by the low voltage detector 312 of the fuse memory circuit 310 is low level L. During this period, the operating voltage VDDREG of the fuse register 314 of the fuse memory circuit 310 returns to the second voltage V2, that is, VCC (e.g., 1.8V). At the same time, the capacitor C is also charged.

In this way, by disposing the fuse memory circuit 310 independently from the peripheral circuit group 100 and the peripheral circuit group 200, when the memory system 10 enters the DPD mode, the fuse memory circuit 310 can still operate at the lowest operating voltage. Thus, after the memory system 10 exits the DPD mode, the voltage information, etc. stored in the fuse register 314 of the fuse memory circuit 310 can be provided to the command interface logic unit 102 of the peripheral circuit group 100 without the need to re-store the information stored in fuse memory cells to the fuse register 314. Thus, a recovery time tRES after the memory system 10 exits the DPD mode can be further shortened.

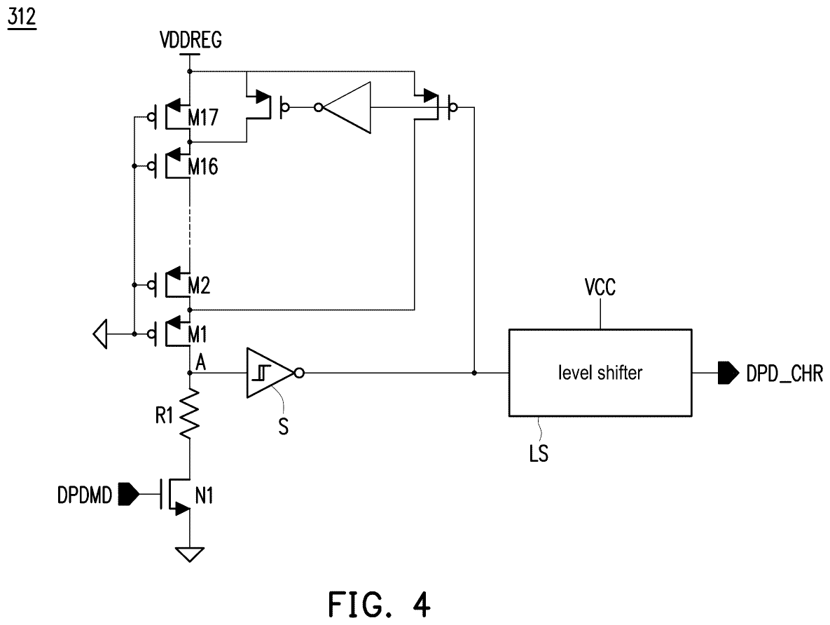

FIG. 4 is a schematic diagram of a low voltage detection circuit 400 in a fuse memory circuit according to an embodiment of the disclosure. As shown in FIG. 4, the upper limit value VH and the lower limit value VL of the low voltage detector 312 are controlled by changing a ratio between the quantity of PMOS transistors between the operating voltage VDDREG and ground to a resistor R1. The low voltage detector 312 includes multiple first transistors, a resistor R1, a second transistor N1, a Schmitt trigger S, and a level shifter LS. The first transistors are, for example, multiple PMOS transistors connected in series with each other, e.g., M1 to M7 shown in FIG. 4. The second transistor is, for example, an NMOS transistor.

The PMOS transistors M1 to M17 are connected in series with the resistor R1. One terminal of the resistor R1 is coupled to a node A (one terminal of the PMOS transistor M1), and the other terminal of the resistor R1 is coupled to an NMOS transistor N1. Gates of the PMOS transistors M1 to M17 can all be grounded. In addition, a gate of the NMOS transistor N1 is controlled by the DPD mode signal DPDMD. In addition, an input terminal of the Schmitt trigger S is coupled to the node A, and an output terminal is coupled to the level shifter LS. When the memory system 10 enters the DPD mode based on the DPD mode signal DPDMD of high level, the NMOS transistor N1 is turned on, thereby causing the low voltage detector 312 to start operating.

As mentioned above, when detecting that the operating voltage VDDREG reaches the upper limit value VH, the low voltage detector 312 transitions through the Schmitt trigger S to output the low voltage detection signal DPD_CHR with low level. Thus, the quantity of the turn-on PMOS transistors M1 to M17 may be used to determine the voltage value of the transition. In addition, the output of the Schmitt trigger S is further transmitted to the level shifter LS to perform level shifting. This is because the transistor 318, a logic control circuit 312, etc. need to operate in the VCC voltage domain, so the level shifter LS is required to shift the level.

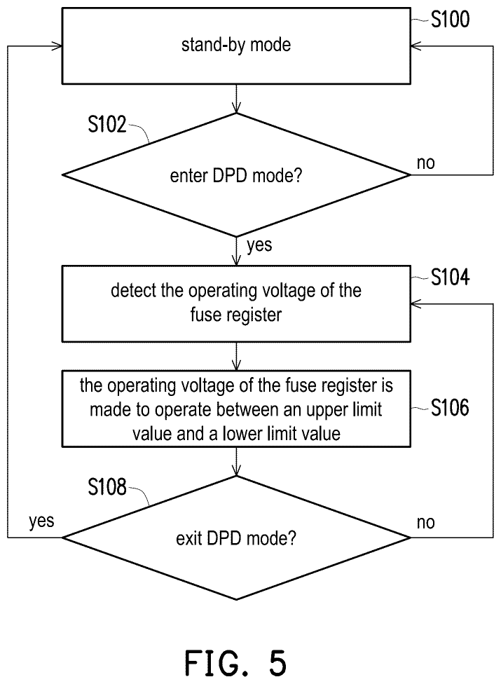

FIG. 5 is a schematic flow chart of a control method according to an embodiment of the disclosure. In step S100, the memory system 10 is in the stand-by mode. Next, in step S102, the memory system 10 determines whether the DPD mode signal DPDMD is received. When the memory system 10 determines that the DPD mode signal DPDMD with high level is received (step S102: yes), the memory system 10 is notified to enter the DPD mode, and step S104 is executed. On the contrary, when the memory system 10 determines that the DPD mode signal DPDMD is low level, the DPD mode is not entered, then the process returns to step S100, and the memory system 10 remains in the stand-by mode.

In step S104, when the memory system 10 enters the DPD mode, based on the DPD mode signal DPDMD of high level, the low voltage detector 312 of FIG. 2 starts to operate and continuously detects the operating voltage VDDREG of the fuse register 316.

In step S106, the operating voltage VDDREG of the fuse register 316 is made to operate between the upper limit value VH and the lower limit value VL, so that the fuse register 316 can maintain operation in the DPD mode. As shown in FIG. 3, after entering the DPD mode, the operating voltage VDDREG starts to decrease from 1.8V, and the transistor 318 is turned off. At this time, the capacitor C starts to provide the operating voltage VDDREG to the fuse register 316. After the capacitor C continues to discharge, the operating voltage VDDREG begins to decrease.

Afterwards, when the low voltage detector 312 detects that the operating voltage VDDREG reaches the lower limit value VL, the low voltage detection signal DPD_CHR of high level is sent. As a result, the transistor 318 is turned on, and begins to charge the capacitor C. When the voltage (the operating voltage VDDREG to be provided) of the capacitor C reaches the upper limit value VH, the low voltage detector 312 sends the low voltage detection signal DPD_CHR of low level, so that the transistor 318 is turned off, and the capacitor C starts to provide the operating voltage VDDREG to the fuse register 316.

In step S108, it is determined whether the memory system 10 is to exit the DPD mode. When the DPD mode signal DPDMD continues to maintain a high level, it indicates that the memory system 10 is not exiting the DPD mode. That is, when the determination in step S108 is “no”, the process returns to step S104. The low voltage detector 312 continues to detect the operating voltage VDDREG, and through the operation of the low voltage detector 312, the operating voltage VDDREG of the fuse register 316 is operated between the upper limit value VH and the lower limit value VL. On the contrary, in step S108, if it is determined that the memory system 10 is to exit the DPD mode, the DPD mode signal DPDMD becomes low level, then the process return to step S100, the memory system 10 exits the DPD mode and returns to the stand-by mode.

To sum up, with the above circuit structure, the operating voltage VDDREG of the fuse register 316 is relatively low, and the leakage current of the element is also reduced because a cross-voltage of the element is reduced. As a result, the time for recharging the capacitor C becomes longer, and the DPD mode current ICC2 may be less than 1 μA.

In addition, according to the implementation of the disclosure, since the fuse register is independent of the first and second peripheral circuit groups and is powered by another voltage domain, the state of the fuse register can be maintained when the memory system enters the DPD mode. In other words, even in the DPD mode, the fuse register can keep storing the voltage information for the operation of the memory system. Therefore, it is not necessary to re-store the voltage information in the fuse register after the memory system exits the DPD mode. Thus, the recovery time tRES may be reduced to less than 3 μs.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A control device, configured to control a memory system, the control device comprising:
a first peripheral circuit group, driven by a first voltage when the memory system is in a stand-by mode;
a second peripheral circuit group, coupled to the first peripheral circuit group, driven by a second voltage when the memory system is in the stand-by mode;
a third peripheral circuit group, coupled between the first peripheral circuit group and the second peripheral circuit group, wherein a structure of the third peripheral circuit group is a fuse memory circuit, when the memory system enters a deep power down mode based on a deep power down mode signal being a first logical value, the fuse memory circuit operates an operating voltage between an upper limit value and a lower limit value, and the upper limit value is lower than the second voltage.

2. The control device according to claim 1, wherein the fuse memory circuit further comprises:
a fuse register, configured to store voltage information for an operation of the memory system;
a low voltage detector, configured to detect an operating voltage of the fuse register in the deep power down mode, output a low voltage detection signal based on magnitude of the operating voltage, enable the low voltage detection signal to become the first logical value when the operating voltage reaches the lower limit value, and enable the low voltage detection signal to become a second logical value when the operating voltage reaches the upper limit value;
a logic control circuit, coupled to the low voltage detector to receive the deep power down mode signal and the low voltage detection signal to perform a logic operation;
a transistor, having a control terminal, a first terminal, and a second terminal, the control terminal being coupled to output of the logic control circuit, and the first terminal being coupled to the second voltage, wherein the transistor switches based on a result of the logic operation; and
a capacitor, having a first terminal coupled to the second terminal of the transistor, and a second terminal coupled to ground,
wherein the second terminal of the transistor and the first terminal of the capacitor are coupled to the fuse register.

3. The control device according to claim 2, wherein the logical control circuit further comprises:
an inverter, receiving the deep power down mode signal; and
an NOR gate, receiving the inverted deep power down mode signal and the low voltage detection signal, output of the NOR gate being coupled to a control terminal of the transistor.

4. The control device according to claim 3, wherein the transistor is a PMOS transistor.

5. The control device according to claim 2, wherein the low voltage detector at least comprises:
a plurality of first transistors, connected in series with each other;
a resistor, having a first terminal and a second terminal, and the first terminal of the resistor being connected in series with the first transistors;
a second transistor, connected in series with the second terminal of the resistor, and a control terminal of the second transistor being configured to receive the deep power down mode signal;
a Schmitt trigger, having an input terminal and an output terminal, the input terminal of the Schmitt trigger being coupled to the first terminal of the resistor; and
a level shifter, coupled to the output terminal of the Schmitt trigger, outputting the low voltage detection signal.

6. The control device according to claim 1, wherein an upper limit value and a lower limit value of the low voltage detector are determined by a ratio of a quantity of the first transistors to the resistor.

7. The control device according to claim 5, wherein each of the first transistors is a PMOS transistor, and the second transistor is an NMOS transistor.

8. The control device according to claim 2, wherein
the transistor is a PMOS transistor,
when the memory system exits the deep power down mode, the transistor is turned on and provides the second voltage as the operating voltage of the fuse register.

9. The control device according to claim 2, wherein the first peripheral circuit group at least comprises a command interface logic unit, and the fuse register is coupled to the command interface logic unit to provide the voltage information for the operation of the memory system.

10. A memory system, comprising:
a memory array; and
a control device, configured to control the memory array, wherein the control device comprises:
a first peripheral circuit group, coupled to the memory array, driven together with the memory array by a first voltage when the memory array is in a stand-by mode;
a second peripheral circuit group, coupled to the memory array and the first peripheral circuit group, driven by a second voltage when the memory array is in the stand-by mode;
a third peripheral circuit group, coupled between the first peripheral circuit group and the second peripheral circuit group, wherein a structure of the third peripheral circuit group is a fuse memory circuit, when the memory system enters a deep power down mode based on a deep power down mode signal being a first logical value, the fuse memory circuit operates an operating voltage between an upper limit value and a lower limit value, and the upper limit value is lower than the second voltage.

11. The memory system according to claim 10, wherein the fuse memory circuit further comprises:
a fuse register, configured to store voltage information for an operation of the memory array;
a low voltage detector, configured to detect an operating voltage of the fuse register in the deep power down mode, output a low voltage detection signal based on magnitude of the operating voltage, enable the low voltage detection signal to become the first logical value when the operating voltage reaches the lower limit value, and enable the low voltage detection signal to become a second logical value when the operating voltage reaches the upper limit value;
a logic control circuit, coupled to the low voltage detector to receive the deep power down mode signal and the low voltage detection signal to perform a logic operation;
a transistor, having a control terminal, a first terminal, and a second terminal, the control terminal being coupled to output of the logic control circuit, and the first terminal being coupled to the second voltage, wherein the transistor switches based on a result of the logic operation; and
a capacitor, having a first terminal coupled to the second terminal of the transistor, and a second terminal coupled to ground,
wherein the second terminal of the transistor and the first terminal of the capacitor are coupled to the fuse register.

12. The memory system according to claim 11, wherein the logical control circuit further comprises:
an inverter, receiving the deep power down mode signal; and
an NOR gate, receiving the inverted deep power down mode signal and the low voltage detection signal, output of the NOR gate being coupled to a control terminal of the transistor.

13. The memory system according to claim 12, wherein the transistor is a PMOS transistor.

14. The memory system according to claim 11, wherein the low voltage detector at least comprises:
a plurality of first transistors, connected in series with each other;
a resistor, having a first terminal and a second terminal, and the first terminal of the resistor being connected in series with the first transistors;
a second transistor, connected in series with the second terminal of the resistor, and a control terminal of the second transistor being configured to receive the deep power down mode signal;
a Schmitt trigger, having an input terminal and an output terminal, the input terminal of the Schmitt trigger being coupled to the first terminal of the resistor; and
a level shifter, coupled to the output terminal of the Schmitt trigger, outputting the low voltage detection signal.

15. The memory system according to claim 10, wherein an upper limit value and a lower limit value of the low voltage detector are determined by a ratio of a quantity of the first transistors to the resistor.

16. The memory system according to claim 14, wherein each of the first transistors is a PMOS transistor, and the second transistor is an NMOS transistor.

17. The memory system according to claim 11, wherein
the transistor is a PMOS transistor,
when the memory system exits the deep power down mode, the transistor is turned on and provides the second voltage as the operating voltage of the fuse register.

18. The memory system according to claim 11, wherein the first peripheral circuit group at least comprises a command interface logic unit, and the fuse register is coupled to the command interface logic unit to provide the voltage information for the operation of the memory array.

19. A control method for controlling a memory system, the memory system having a control device, the control device comprising a first peripheral circuit group operating at a first voltage, a second peripheral circuit group operating at a second voltage, and a third peripheral circuit group disposed independently from the first peripheral circuit group and the second circuit group, the control method comprising:
determining whether the memory system is going to enter a deep power down mode;
when determining that the memory system enters the deep power down mode, detecting an operating voltage of a fuse register in the third peripheral circuit group, wherein the fuse register is configured to store operation information for an operation of the memory system; and
until existing the deep power down mode, based on the detected operating voltage, enabling the operating voltage of the fuse register to be between an upper limit value and a lower limit value, the upper limit value being lower than the second voltage.

20. The control method according to claim 19 further comprising: continuing to perform the following steps:
when detecting that the operating voltage reaches the lower limit value, enabling the operating voltage to rise; and
when detecting that the operating voltage reaches the upper limit value, stopping the rise of the operating voltage.
